(19) United States
(12) Patent Application Publication
(10) Pub. No.: US 2015/0270250 A1
(43) Pub. Date: Sep. 24, 2015

(54) SEMICONDUCTOR DEVICE

(71) Applicant: PS4 LUXCO S.A.R.L., Luxembourg (LU)

(72) Inventor: Onda Takamitsu, Tokyo (JP)

(21) Appl. No.: 14/438,568

(22) PCT Filed: Nov. 5, 2013
(86) PCT No.: PCT/JP2013/079871

§ 371 Date: Apr. 24, 2015

(30) Foreign Application Priority Data
Nov. 13, 2012 (JP) 2012-249359

(51) Int. Cl. H01L 25/18; H01L 23/48; H01L 23/528; H01L 23/00; G11C 29/12; H01L 21/66; H01L 25/065

(52) U.S. Cl. CPC H01L 25/18; H01L 22/32; H01L 23/481; H01L 25/0657; H01L 24/17; G11C 29/1201; H01L 23/528; H01L 2224/16146; H01L 2225/06513; H01L 2225/06517; H01L 2225/06541; H01L 2225/06565

(57) ABSTRACT

[Problem] To match operating conditions during normal operations in which a bump electrode is used and operating conditions during test operations when a test pad is used.

[Solution] A semiconductor device comprises a bump electrode (PLV0), a test pad (TPV), internal circuitry (31), power source wiring (V1) which connects the bump electrode (PLV0) and a node (N1), power source wiring (V2) which connects the test pad (TPV) and the node (N1), and power source wiring (V3) which connects the node (N1) and the internal circuitry (31). The power source wiring (V1) and the power source wiring (V2) are designed so that the resistance values are substantially equal to each other. Thus, because the operating conditions during normal operation and during test operations are substantially the same, the yield rate can be improved due to the elimination of mistaken determinations of non-defective products, or conversely, mistaken determinations of defective products.

### TECHNICAL FIELD

The present invention relates to a semiconductor device, and in particular relates to a semiconductor device provided with bump electrodes and test pads.

### BACKGROUND ART

In the manufacturing process of a semiconductor chip such as a DRAM (Dynamic Random Access Memory), operational tests are performed in the wafer state by bringing the distal end of a probe into contact with a bonding pad provided on the semiconductor chip. However, for the past few years there have been semiconductor chips which do not have bonding pads. For example, in a stacked-type semiconductor chip employing through-electrodes, the semiconductor chips are electrically connected to one another by way of the through-electrodes and bump electrodes provided at both ends of the through-electrodes, and thus bonding pads for wire bonding are not required. A known example of a stacked-type semiconductor device is that described in patent literature article 1.

The semiconductor chips used in stacked-type semiconductor devices must also be subjected to operational tests in the wafer state. Therefore semiconductor chips of this type are sometimes provided with test pads to make it possible for operational tests to be conducted in the wafer state. When conducting operational tests in the wafer state, power-supply potentials or signals that would normally be supplied from the bump electrodes are supplied from the test pads, by bringing the distal end of the probe into contact with the test pad.

### PATENT LITERATURE

Patent literature article 1: Japanese Patent Kokai 2004-327474

### SUMMARY OF THE INVENTION

### Problems to be Resolved by the Invention

However, in a conventional semiconductor chip provided with test pads, the resistance of wiring lines connecting the bump electrodes to internal circuits is not necessarily the same as the resistance of wiring lines connecting the test pads to the internal circuits, and it is therefore difficult to conduct accurate operational tests. There are thus problems in that a semiconductor chip which operates without problem during normal operation may be mistakenly determined to be faulty in an operational test, or, conversely, a semiconductor chip in which an operational failure occurs during normal operation may be mistakenly determined to be non-defective in an operational test. All such problems reduce the semiconductor chip yield, and therefore result in an increase in the manufacturing cost.

### Means of Overcoming the Problems

A semiconductor device according to one aspect of the present invention is characterized in that it comprises a bump electrode, a test pad, an internal circuit, a first wiring line portion connecting the bump electrode to a wiring line node, a second wiring line portion connecting the test pad to the wiring line node, and a third wiring line portion connecting the wiring line node to the internal circuit, and in that the resistance values of the first wiring line portion and the second wiring line portion are substantially equal to one another.

A semiconductor device according to another aspect of the present invention comprises a plurality of semiconductor chips which are stacked on one another, and is characterized in that: each of the plurality of semiconductor chips is provided with a bump electrode, a test pad, an internal circuit, a first wiring line portion connecting the bump electrode to a wiring line node, a second wiring line portion connecting the test pad to the wiring line node, and a third wiring line portion connecting the wiring line node to the internal circuit; at least one of the plurality of semiconductor chips is provided with a through-electrode provided penetrating through said semiconductor chip; the internal circuits contained in each of the plurality of semiconductor chips are commonly connected by way of the bump electrodes and the through-electrodes; and the resistance values of the first wiring line portion and the second wiring line portion contained in each of the plurality of semiconductor chips are substantially equal to one another.

### Advantages of the Invention

According to the present invention, the resistance value of the wiring line connecting the bump electrode to the internal circuit is substantially equal to the resistance value of the wiring line connecting the test pad to the internal circuit, and therefore the operating conditions during normal operation and during test operation are substantially the same. Situations in which products are mistakenly determined to be non-defective, or are conversely mistakenly determined to be defective, are thus eliminated, and it is therefore possible to improve the yield.

### BRIEF EXPLANATION OF THE DRAWINGS

FIG. 1 (a) is a schematic cross-sectional view used to describe the structure of a semiconductor device 1 according to a preferred mode of embodiment of the present invention, and (b) is a schematic cross-sectional view used to describe a mounting example of the semiconductor device 1.

FIGS. 2 (a) and (b) are each drawings illustrating the state of connection of through-electrodes TSV provided in semiconductor chips C1 to C4.

FIG. 3 is a cross-sectional view illustrating the structure of the through-electrodes TSV1 illustrated in FIG. 2 (a).

FIG. 4 is a cross-sectional view illustrating the structure of the through-electrodes TSV2 illustrated in FIG. 2 (b).

FIG. 5 is a cross-sectional view illustrating the structure of a test pad TP.

FIG. 6 is a plan view of a main surface C1a of a semiconductor chip C1.

FIG. 7 is a block diagram used to describe the configuration of a channel Ch_a.

FIG. 8 is an enlarged view of region D illustrated in FIG. 6.

FIG. 9 is a drawing used to describe a first modified example.

FIG. 10 is a drawing used to describe a second modified example.

FIG. 11 is a drawing used to describe another mounting example of the semiconductor device 1.

### MODES OF EMBODYING THE INVENTION

Preferred modes of embodiment of the present invention will now be described in detail with reference to the accompanying drawings.

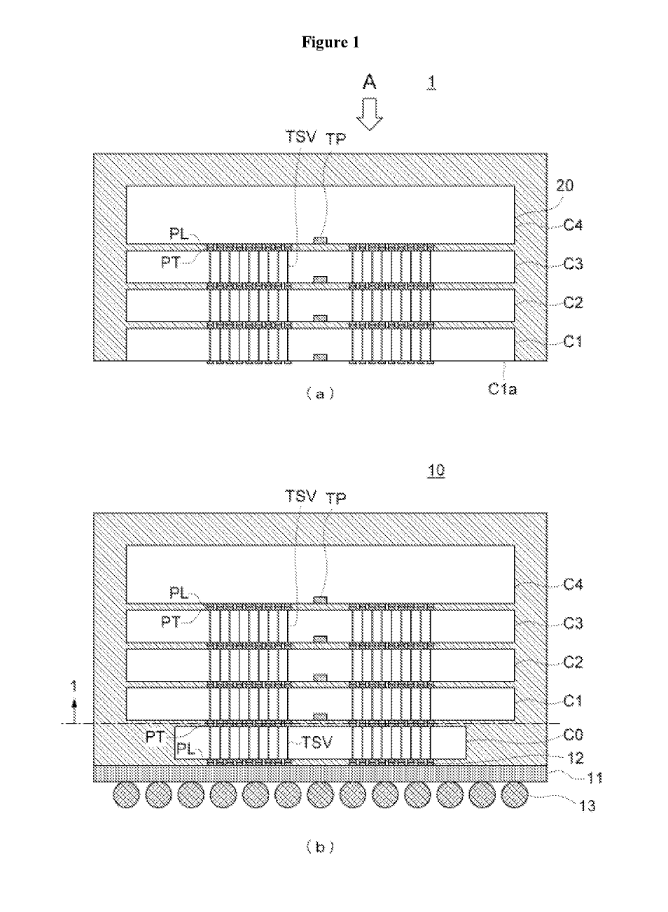

FIG. 1 (a) is a schematic cross-sectional view used to describe the structure of a semiconductor device 1 according to a preferred mode of embodiment of the present invention. The overall structure of the semiconductor device 1 will first be described in outline, and then aspects of the configuration that are characteristic to the present invention will be described in detail.

As illustrated in FIG. 1 (a), the semiconductor device 1 according to this mode of embodiment is what is known as a wide I/O-type DRAM, having a structure in which three semiconductor chips C1 to C3 having bump electrodes PL, through-electrodes TSV and bump electrodes PT, and one semiconductor chip C4 having bump electrodes PL but not having through-electrodes TSV or bump electrodes PT are stacked on one other successively in order from the bottom. It should be noted that the semiconductor chips C1 to C3 are three semiconductor chips which have the same function and structure as one another, and which are produced using the same manufacturing mask. Further, the semiconductor chip C4 has substantially the same function and structure as the semiconductor chips C1 to C3 except that it does not have through-electrodes TSV or bump electrodes PT.

The semiconductor chips C1 to C4 are chips which each function on their own as what is known as a DRAM, comprising a memory cell array and memory cell array peripheral circuits (which are not shown in FIG. 1 (a)). The peripheral circuits include, for example, data input and output circuits which perform input and output of data between the memory cell array and the outside, and control circuits which control the input and output of data in accordance with commands input from the outside. Memory cell arrays and peripheral circuits are sometimes referred to hereinafter generically as ‘internal circuits’. The semiconductor chips C1 to C4 are sealed in resin in a stacked state, and function as an integrally-packaged memory device.

FIG. 1 (b) illustrates a mounting example of the semiconductor device 1. As illustrated in FIG. 1(b), the semiconductor device 1 is stacked together with a controller chip C0 on a package substrate 11 (interposer) to form a composite semiconductor device 10. A plurality of solder bumps 13 are provided on the reverse surface of the package substrate 11. The controller chip C0 is a semiconductor chip in which logic circuits controlling the operation of each of the four semiconductor chips C1 to C4, which are DRAMs, are formed on the main surface of a semiconductor substrate, and the controller chip C0 is also known as an SOC (System On Chip). The controller chip C0 and the semiconductor chip 1 are sealed integrally in resin, as illustrated in FIG. 1 (b). The configuration of the composite semiconductor device 10 will be described in detail later.

Each semiconductor chip C1 to C4 has a semiconductor substrate (silicon substrate) 20, as illustrated in FIG. 1 (a), and the internal circuits discussed hereinabove are formed on the main surface (the lower surface in FIG. 1) of the semiconductor substrate 20. With regard to the semiconductor chips C1 to C3, the bump electrodes PT are formed on the reverse surface (the upper surface in FIG. 1), and the bump electrodes P1 are formed on the main surface. As illustrated in the drawing, the semiconductor chips C1 to C3 are connected to one another by way of the through-electrodes TSV which are provided penetrating through the semiconductor substrates 20. Meanwhile, with regard to the semiconductor chip C4, the bump electrodes PL are formed on the main surface, but the reverse surface bump electrodes PT and the through-electrodes TSV are not formed.

The reason that the reverse surface bumps PT and the through-electrodes TSV are not formed on the semiconductor chip C4 is that the semiconductor chip C4 is the uppermost semiconductor chip in the semiconductor device 1, and it is therefore not necessary for signals supplied from the bump electrodes PT on the semiconductor chip C3 to be supplied further to another semiconductor chip. If, in this way, the through-electrodes TSV and the bump electrodes PT are not formed on the semiconductor chip C4, then the semiconductor chip C4 can be made thicker than the semiconductor chips C1 to C3, as illustrated by way of example in FIG. 1 (a). As a result, when the semiconductor device 1 is being manufactured, chip deformation resulting from thermal stresses (thermal stresses generated during the stacking of the semiconductor chips C1 to C4) can be suppressed. However, a semiconductor chip having the same structure as the semiconductor chips C1 to C3 may of course be used as the semiconductor chip C4.

The bump electrodes PL and the internal circuits are connected to one another by way of wiring lines provided within the main surface of each semiconductor chip. Further, the bump electrodes PT on the semiconductor chips C1 to C3 are in contact with the bump electrodes PL on another semiconductor chip directly above said semiconductor chip. By this means, the bump electrodes on the semiconductor chips C1 to C4 are led out to the main surface C1a of the semiconductor chip C1 in the lowermost layer.

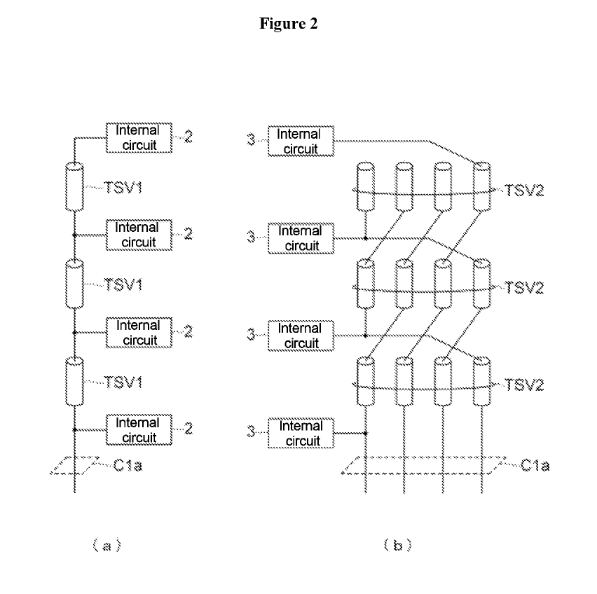

FIGS. 2 (a) and (b) are each drawings illustrating the state of connection of the through-electrodes TSV provided in the semiconductor chips C1 to C4. In FIGS. 2 (a) and (b), illustrations of the bump electrodes PT and PL have been omitted. The states of connection of the through-electrodes TSV are of two types, namely the type illustrated in FIG. 2 (a) and the type illustrated in FIG. 2 (b), and the corresponding through-electrodes TSV are hereinafter respectively referred to as through-electrodes TSV1 and TSV2.

The through-electrodes TSV1 illustrated in FIG. 2 (a) are short-circuited to the through-electrodes TSV1 in the other layers, said through-electrodes TSV1 in the other layers being provided in the same position in a plan view as seen in the stacking direction, in other words as seen in the direction of the arrow A in FIG. 1 (a). In other words, as illustrated in FIG. 2 (a), the upper and lower through-electrodes TSV1 provided in the same position, as seen in a plan view, are short-circuited together, these through-electrodes TSV1 forming a single current path. This current path is connected to the internal circuits 2 in the semiconductor chips C1 to C4. Therefore, input signals (command signals, address signals, clock signals and the like) supplied to this current path from the outside by way of the main surface C1a of the semiconductor chip C1 are input in common to the internal circuits 2 of the semiconductor chips C1 to C4. Further, output signals (data and the like) supplied to this current path from the internal circuits 2 of the semiconductor chips C1 to C4 are wire-ORed and output to the outside from the main surface C1a of the semiconductor chip C1.

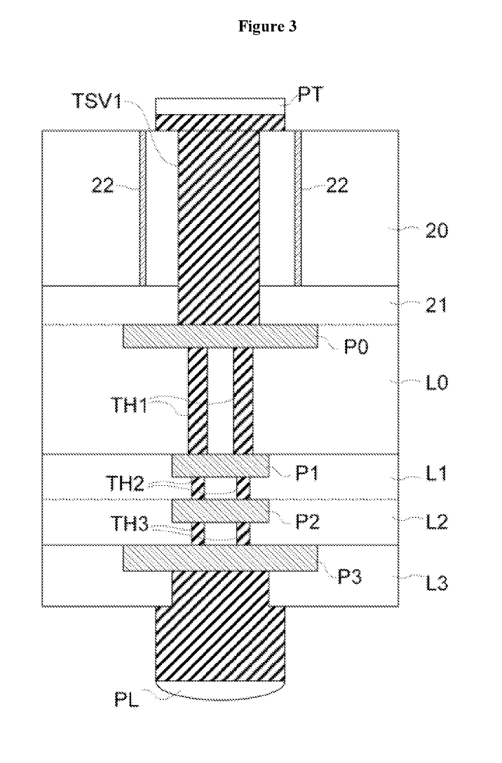

FIG. 3 is a cross-sectional view illustrating the structure of the through-electrodes TSV1. As illustrated in the drawing, the through-electrode TSV1 is provided penetrating through the semiconductor substrate 20 and an interlayer insulating film 21 on the obverse surface thereof. An insulating ring 22 is provided at the periphery of the through-electrode TSV1, thereby ensuring insulation between the through-electrode TSV1 and a transistor region (a region in which transistors, which are constituents of the internal circuits, are formed). It should be noted that the insulating ring 22 may be provided in duplicate, and by so doing the electrostatic capacitance between the through-electrode TSV1 and the semiconductor substrate 20 is reduced.

The lower end of the through-electrode TSV1 is connected by way of pads P0 to P3 provided in wiring line layers L0 to L3, and a plurality of through-hole electrodes TH1 to TH3 connecting the pads together, to the bump electrode PL (obverse surface bump) provided on the main surface of the semiconductor chip. Meanwhile, the upper end of the through-electrode TSV1 is connected to the bump electrode PT (reverse surface bump) on the semiconductor chip. The bump electrode PT is connected to the bump electrode PL provided on the semiconductor chip in the layer above. By this means, two through-electrodes TSV1 provided in the same position, as seen in a plan view, are in a state in which they are short-circuited to each other. The connections with the internal circuit 2 illustrated in FIG. 2 (a) are effected by way of internal wiring lines (which are not shown in the drawing) led out from the pads P0 to P3 provided in the wiring line layers L0 to L3.

The through-electrodes TSV2 illustrated in FIG. 2 (b) are short-circuited to the through-electrodes TSV2 in the other layers, said through-electrodes TSV2 in the other layers being provided in different positions, as seen in a plan view. More specifically, the semiconductor chips C1 to C3 are each provided with four (=the number of layers in the stack) through-electrodes TSV2, in the same positions, as seen in a plan view. Of the four through-electrodes TSV2, the through-electrode TSV2 in a specific position (in FIG. 2 (b), the left-most through-electrode TSV2), as seen in a plan view, is connected to the internal circuit 3 in the same semiconductor chip C1 to C3. Further, a total of three through-electrodes TSV2, one from each layer, provided in different positions as seen in a plan view, are short-circuited to one another, thereby forming four current paths, each extending from the semiconductor chip C4 to the semiconductor chip C1. The lower end of each current path is exposed at the main surface C1a. Further, of these four current paths, the path that is not connected to any of the internal circuits 3 in the semiconductor chips C1 to C3 is connected at its upper end to the internal circuit 3 in the semiconductor chip C4. Information can therefore be input selectively into the internal circuits 3 on each level, by way of these current paths. Specific examples of such information that can be mentioned include chip select signals and clock enable signals.

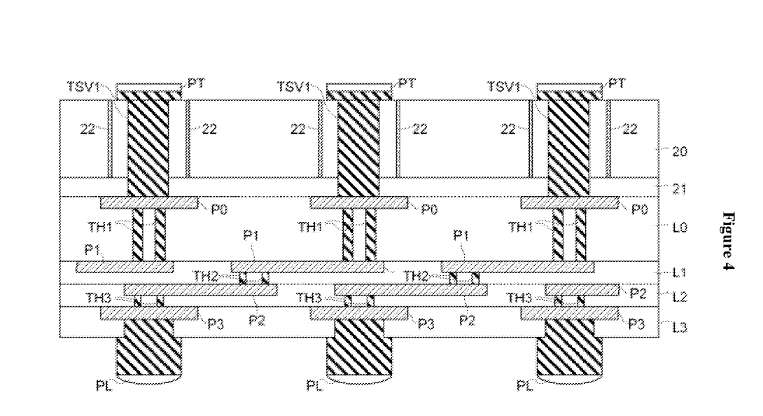

FIG. 4 is a cross-sectional view illustrating the structure of the through-electrodes TSV2. As illustrated in the drawing, the through-electrodes TSV2 differ from the through-electrodes TSV1 in that the pads P1 and P2 in the same planar position are not connected by way of through-hole electrodes TH2, but the pads P1 and P2 in different planar positions are connected by way of the through-hole electrodes TH2. Only three through-electrodes TSV2 are illustrated in FIG. 4, but in practice the through-electrodes TSV2 are provided, in each semiconductor chip C1 to C3, in a number equivalent to the number of chips (four), for each signal.

The description now returns to FIG. 1 (a). In addition to the bump electrodes PL, test pads TP are also provided on the main surfaces of the semiconductor substrates of the semiconductor chips C1 to C4. The test pads TP are pads with which a probe needle of a tester is brought into contact when the semiconductor chip is being tested in the wafer state, and the test pads TP are connected by way of wiring lines provided within the main surface to one of the plurality of bump electrodes PL provided on the same main surface.

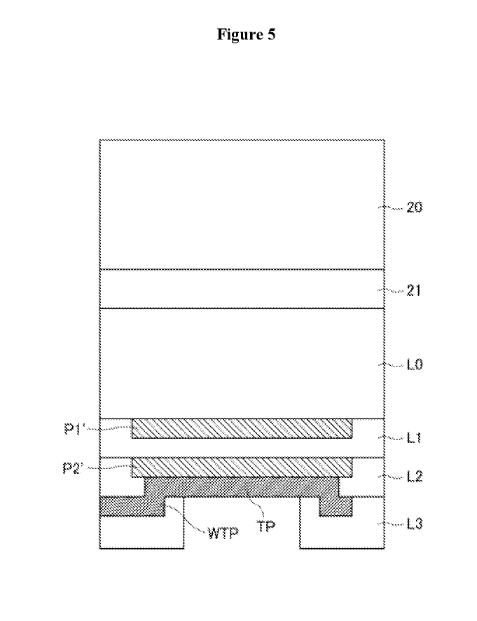

FIG. 5 is a cross-sectional view illustrating the structure of a test pad TP. As illustrated in the drawing, the test pad TP is formed from the same substance as the wiring line layer L3, on a pad electrode P2′ formed as the wiring line layer L2, and is connected to a leader wiring line WTP formed as the wiring line layer L3. The leader wiring line WTP is connected to a bump electrode PL corresponding to the test pad TP, and to an internal circuit corresponding to the test pad TP. It should be noted that instead of the wiring line layer L3, the wiring line layers L1 and L2, and/or through-hole electrodes TH1 and 2 may be interposed between the bump electrode PL corresponding to the test pad TP and the internal circuit corresponding to the test pad TP. Further, as illustrated in FIG. 5, a pad electrode P1′ may be disposed below (above, in the drawing) the pad electrode P2′. By disposing the pad electrode P1′, the strength when the probe of the test device touches the test pad TP can be increased.

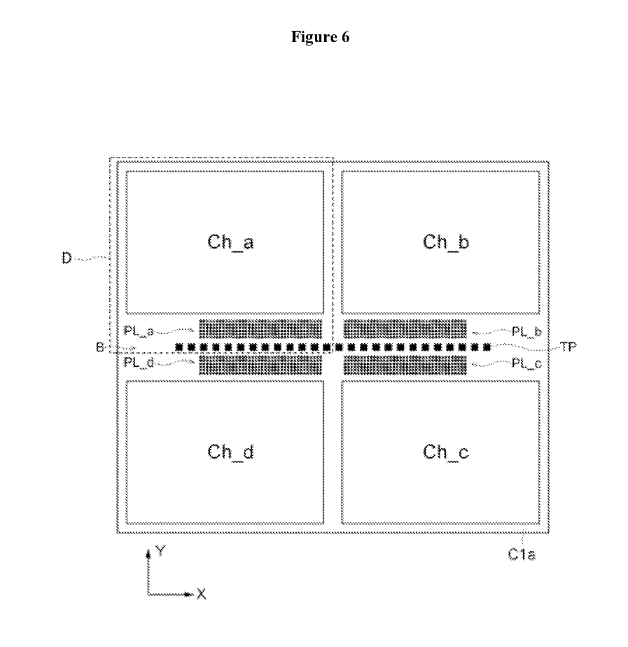

FIG. 6 is a plan view of the main surface C1a of the semiconductor chip C1. Although not shown in the drawings, the main surfaces of the other semiconductor chips C2 to C4 also have the same structure. As illustrated in FIG. 6, four channels (memory portions) Ch_a to Ch_d, a plurality of bump electrodes PL_a to PL_d corresponding respectively to the channels Ch_a to Ch_d, and a plurality of test pads TP are provided on the main surface C1a. The channels Ch_a to Ch_d are semiconductor circuits formed independently of one another in such a way as to be capable of exchanging various types of signal, for example command signals, address signals and data signals, with the outside, and each channel functions as a self-contained DRAM. In other words, the semiconductor chip C1 is configured in such a way that it can perform various operations as a DRAM, such as read operations, write operations and refresh operations, for each channel independently.

As illustrated in FIG. 6, the channels Ch_a and Ch_b are disposed on one side in the Y-direction, and the channels Ch_c and Ch_d are disposed on the other side in the Y-direction. A bump region B is provided between the channels Ch_a and Ch_b and the channels Ch_c and Ch_d, and the bump electrodes PL_a to PL_d and the test pads TP are disposed in this bump region B. More specifically, the bump electrodes PL_a to PL_d are respectively disposed side-by-side in a plurality of rows within the bump region B in the vicinity of the corresponding channel, and the test pads TP are disposed side-by-side in one row in a region between the bump electrodes PL_a and PL_b and the bump electrodes PL_c and PL_d. As illustrated in FIG. 6, the surface area and the spacing of the test pads TP are greater than the surface area and the spacing of the bump electrodes PL. This is in order to make it easier for the probe needle of the tester to be brought into contact therewith. Testing the semiconductor device 1 using such test pads TP in this way makes it possible to perform the testing without damaging the bump electrodes PL and the through-electrodes TSV of the semiconductor chip.

As illustrated in FIG. 1 (b), the same bump electrodes PT and PL as on the semiconductor chips C1 to C3 are provided respectively on the reverse surface and the main surface of the controller chip C0. The bump electrodes PT are connected to the bump electrodes PL on the semiconductor chip C1. Meanwhile, the bump electrodes PL are connected to bump electrodes 12 (external terminals) provided on the reverse surface of the package substrate 11. Further, as illustrated in FIG. 1 (b), through-electrodes TSV are also provided in the semiconductor substrate of the controller chip C0, and the bump electrodes PT and PL and the internal circuits in the controller chip C0 are connected to one another by way of these through-electrodes TSV.

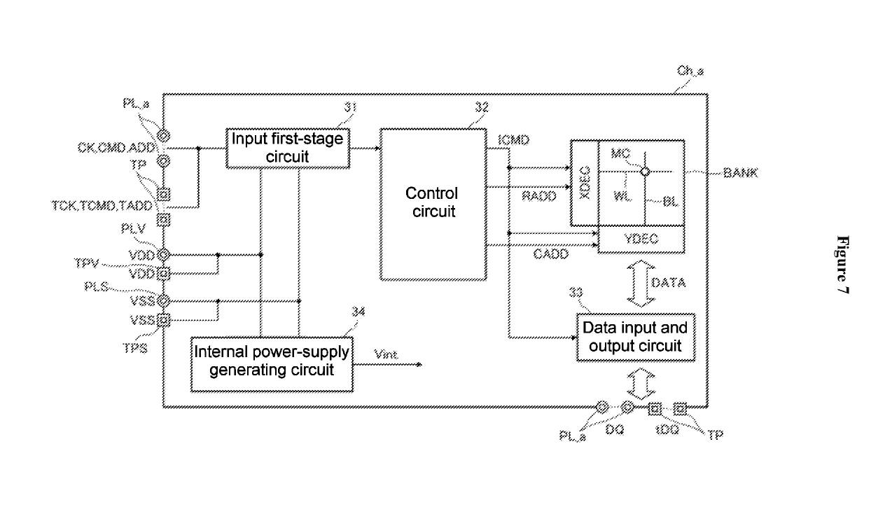

FIG. 7 is a block diagram used to describe the configuration of the channel Ch_a.

As illustrated in FIG. 7, a plurality of bump electrodes PL_a are allocated to the channel Ch_a. The plurality of bump electrodes PL_a allocated to the channel Ch_a include bump electrodes for control, for inputting a clock signal CK, a command signal CMD, an address signal ADD and the like, and bump electrodes for data, for inputting and outputting data DQ, and also a bump electrode for power supply PLV, for supplying an external power-supply potential VDD, and a bump electrode for power supply PLS, for supplying a ground potential VSS. There are test pads TP corresponding respectively to the bump electrodes for control and the bump electrodes for data PL_a. It should be noted that the test pads TP corresponding to the bump electrodes for control and the bump electrodes for data PL_a are not allocated only to the channel Ch_a, but are allocated in common to the four channels Ch_a to Ch_d. Meanwhile, the test pads TP include a test pad TPV for supplying the external power-supply potential VDD, and a test pad TPS for supplying the ground potential VSS. In consideration of layout demands, two sets each of the test pads TPV and TPS are preferably provided, one set being connected in common to the channels A and D, and one set being connected in common to the channels B and C.

The clock input circuit CK, the command signal CMD and the address signal ADD input by way of the bump electrodes PL_a or the test pads TP are supplied to an input first-stage circuit 31. The signals which have been received by the input first-stage circuit 31 are supplied to a control circuit 32. The control circuit 32 generates an internal command ICMD on the basis of the command signal CMD, and also generates a row address RADD or a column address CADD on the basis of the address signal ADD. These operations performed by the control circuit 32 are performed synchronized with the clock signal CK.

More specifically, if the command signal CMD indicates an active command, then the control circuit 32 generates an internal command ICMD indicating a row access, and on the basis of this a row decoder XDEC is activated. Meanwhile, if the command signal CMD indicates a read command or a write command, then the control circuit 32 generates an internal command ICMD indicating a column access, and on the basis of this a column decoder YDEC is activated.

When a command signal CMD indicating an active command is issued, the address signal ADD input synchronously therewith is supplied to the row decoder XDEC as a row address RADD. A word line WL indicated by said row address RADD is thus selected. Meanwhile, when a command signal CMD indicating a read command or a write command is issued, the address signal ADD input synchronously therewith is supplied to the column decoder YDEC as a column address CADD. A bit line BL indicated by said column address CADD is thus selected.

Therefore, by issuing successively an active command and a read command, and inputting synchronously therewith a row address RADD and a column address CADD, data DATA are read from a memory cell MC specified by the row address RADD and the column address CADD. The data DATA read from the memory cell MC are output, by way of the data input and output circuit 33, from the bump electrode PL_a or the test pad TP for data DQ. On the other hand, by issuing successively an active command and a write command, and inputting synchronously therewith a row address RADD and a column address CADD, data DATA input into the bump electrode PL_a or the test pad TP for data DQ are written by way of the data input and output circuit 33 to the memory cell MC specified by the row address RADD and the column address CADD.

Here, at least a portion of the input first-stage circuit 31 and the data input and output circuit 33 operate using the external power-supply potential VDD as a power supply. In contrast, at least a portion of the control circuit 32 operates using an internal power-supply potential Vint, generated by an internal power supply generating circuit 34, as a power supply. The internal power supply generating circuit 34 is a circuit which receives the external power-supply potential VDD and generates the internal power-supply potential Vint on the basis of the external power-supply potential VDD.

A description has been provided hereinabove relating to the configuration and operation of the channel Ch_a, but the configuration and operation of the other channels Ch_b to Ch_d are the same.

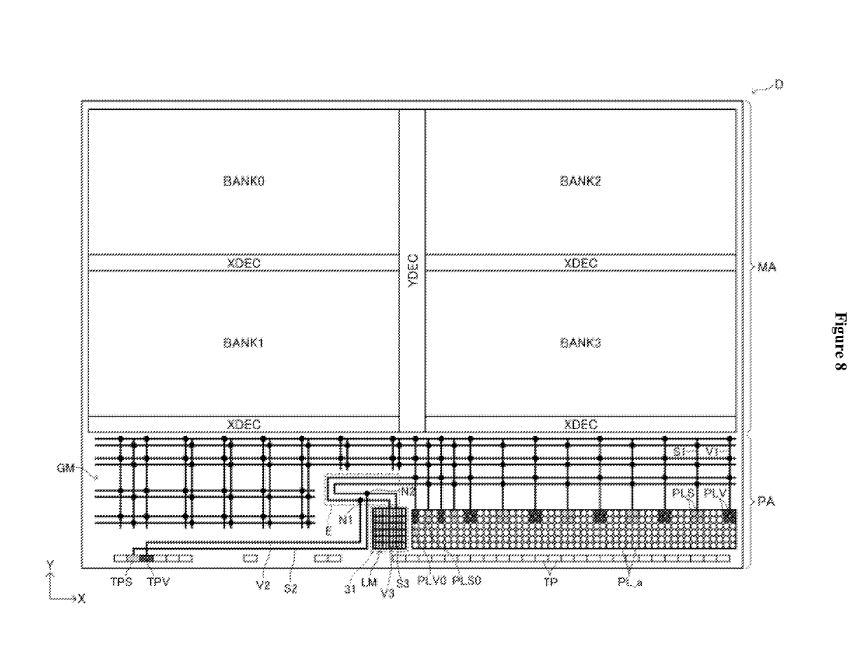

FIG. 8 is an enlarged view of region D illustrated in FIG. 6.

The region D is the region in which the channel Ch_a is disposed, and as illustrated in FIG. 8 it comprises a memory region MA and a peripheral circuit region PA. In the memory region MA are formed four memory banks BANK0 to BANK3 disposed in a matrix formation, row decoders XDEC disposed along one edge in the X-direction of each memory bank BANK0 to BANK3, and a column decoder YDEC disposed between the memory banks BANK0 and BANK1 and the memory banks BANK2 and BANK3. The memory banks BANK0 to BANK3 are regions in which multiple memory cells MC are disposed.

Meanwhile, the peripheral circuit region PA includes a region in which the plurality of bump electrodes PL_a and the plurality of test pads TP are disposed. As illustrated in FIG. 8, in the bump electrodes PL_a, the bump electrodes PLV to which the external power-supply potential VDD is supplied are connected to a power-supply wiring line V1, and the bump electrodes PLS to which the ground potential VSS is supplied are connected to a power-supply wiring line S1. It should be noted that a plurality of the bump electrodes PLV and PLS for power supply are provided respectively in order to stabilize the potential. Further, in the test pads TP, the test pad TPV to which the external power-supply potential VDD is supplied is connected to a power-supply wiring line V2, and the test pad TPS to which the ground potential VSS is supplied is connected to a power-supply wiring line S2. The power-supply wiring lines V1 and V2 are short-circuited at a node N1, and the power-supply wiring lines S1 and S2 are short-circuited at a node N2.

The power source wiring line V1 and the power-supply wiring line S1 form global mesh-like wiring lines GM in at least the peripheral circuit region PA. In the structure of the mesh-like wiring lines, power-supply wiring lines V1 and power-supply wiring lines S1 extending in the X-direction, for example, should be formed in a certain wiring line layer, power-supply wiring lines V1 and S1 extending in the Y-direction should be formed in another wiring line layer, and the locations at which these intersect should be connected by way of through-hole conductors. By constructing the power-supply wiring lines V1 and S1 in the shape of a mesh, their resistances can be reduced even if the wiring-line distance is long.

In the example illustrated in FIG. 8, power-supply wiring lines V3 and power source wiring lines S3 form local mesh-like wiring lines LM in a region in which the input first-stage circuit 31 is disposed. The power-supply wiring lines V3 are connected to the node N1, and therefore fulfill the role of supplying the external power-supply potential VDD to the input first-stage circuit 31. Meanwhile, the power-supply wiring lines S3 are connected to the node N2, and therefore fulfill the role of supplying the ground potential VSS to the input first-stage circuit 31. The input first-stage circuit 31 includes multiple input receivers which receive multiple signal bits forming the command signal CMD and the address signal ADD, for example, and because the multiple input receivers operate substantially simultaneously, the power-supply potential is liable to vary. In order to prevent such potential variation, the local mesh-like wiring lines LM are provided in the region in which the input first-stage circuit 31 is disposed, in order to reduce the resistance of the power-supply wiring lines.

Then, in this mode of embodiment, the resistance of the wiring line from the node N1 to the bump electrodes PLV, and the resistance of the wiring line from the node N1 to the test pad TPV are designed to be substantially equal. Similarly, the resistance of the wiring line from the node N2 to the bump electrodes PLS, and the resistance of the wiring line from the node N2 to the test pad TPS are designed to be substantially equal. The bump electrodes PLV and PLS referred to here designate bump electrodes PLV0 and PLS0 that are closest to the input first-stage circuit 31. The power-supply wiring lines V1 and S1 between the bump electrodes PLV0 and PLS0 and the nodes N1 and N2 are not in the shape of a mesh. Therefore the resistances of the wiring lines between the bump electrodes PLV0 and PLS0 and the nodes N1 and N2 are determined by the wiring-line distances of the wiring lines V1 and S1.

Here, in terms of actual straight-line distances, the wiring-line distance from the node N1 (N2) to the bump electrode PLV0 (PLS0) is less than the wiring-line distance from the node N1 (N2) to the test pad TPV (TPS). However, in the example illustrated in FIG. 8, the wiring-line distances are made to coincide by taking the power-supply wiring lines V1 and S1 on a circuitous route through a region E, thereby causing their resistances to coincide. In this case the power-supply wiring lines V1 and S1 and the power-supply wiring lines V2 and S2 are preferably formed in the same wiring line layer. Forming these wiring lines in the same wiring line layer eliminates the need to consider differences in the wiring-line material or the wiring-line thickness, thereby simplifying the design.

Thus the characteristics of the power-supply to the input first-stage circuit 31 are substantially the same when the external power-supply potential VDD and the ground potential VSS are supplied from the bump electrodes PLV and PLS, in other words during normal operation, and when the external power-supply potential VDD and the ground potential VSS are supplied from the test pads TPV and TPS, in other words during operational testing in the wafer state. The operation of the input first-stage circuit 31 during normal operation can therefore be accurately reproduced during operational tests in the wafer state. Situations in which products are mistakenly determined to be non-defective during operational testing, or are conversely mistakenly determined to be defective, are thus eliminated, and it is therefore possible to improve the yield.

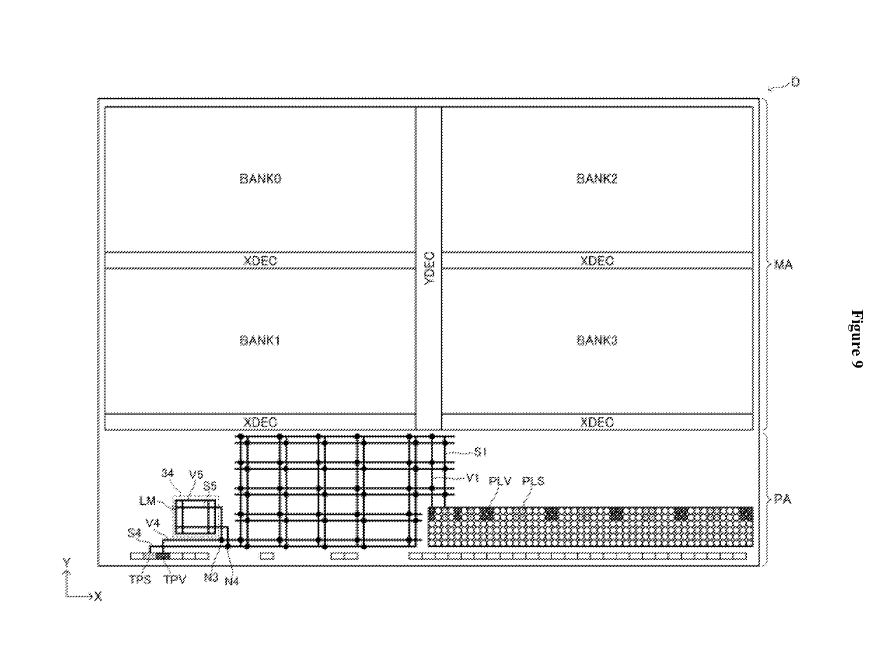

It should be noted that the circuit blocks for which the wiring-line resistances are made to coincide are not limited to the input first-stage circuit 31, and this configuration may also be used for other circuit blocks. For example, in the example illustrated in FIG. 9, the resistances of the wiring lines to the internal power-supply generating circuit 34 are made to coincide.

More specifically, in the region in which the internal power-supply generating circuit 34 is disposed, power-supply wiring lines V5 connected to a node N3 and power-supply wiring lines S5 connected to a node N4 form local mesh-like wiring lines LM. The node N3 is connected to the bump electrodes PLV by way of the power-supply wiring line V1, and is connected to the test pad TPV by way of a power-supply wiring line V4. Similarly, the node N4 is connected to the bump electrodes PLS by way of the power-supply wiring line S1, and is connected to the test pad TPS by way of a power-supply wiring line S4.

Then, in the example illustrated in FIG. 9, the resistance of the wiring line from the node N3 to the bump electrodes PLV, and the resistance of the wiring line from the node N3 to the test pad TPV are designed to be substantially equal. Similarly, the resistance of the wiring line from the node N4 to the bump electrodes PLS, and the resistance of the wiring line from the node N4 to the test pad TPS are designed to be substantially equal. In terms of actual straight-line distances, the wiring-line distance from the node N3 (N4) to the bump electrodes PLV (PLS) is greater than the wiring-line distance from the node N3 (N4) to the test pad TPV (TPS), but because the power-supply wiring lines V1 and the power-supply wiring lines S1 form mesh-like wiring lines GM, their resistance is reduced, and as a result the resistance of the wiring lines can be made to coincide substantially, as described hereinabove. Thus as methods for making the resistances of the wiring line coincide, it is possible to employ not only a method in which the actual wiring-line distances are made to coincide, but also methods in which the design of the wiring line structure is altered, while the actual wiring-line distances differ.

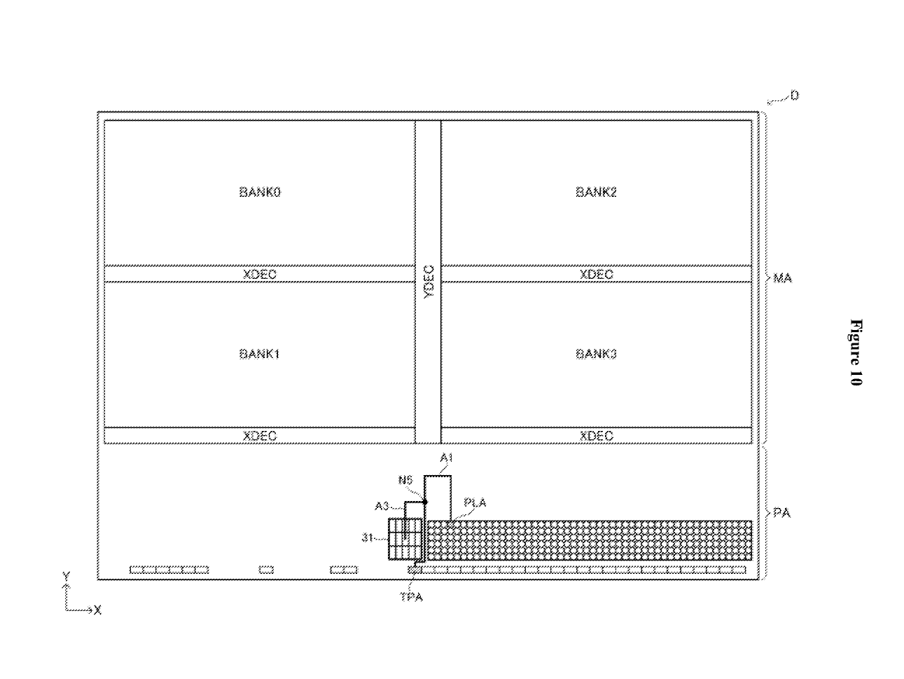

Further, the wiring lines for which the resistance is made to coincide are not limited to the power-supply wiring lines, but may also be signal wiring lines. For example, in the example illustrated in FIG. 10, the wiring-line resistances of signal wiring lines A1 and A2 connected to the input first-stage circuit 31 are made to coincide. The signal wiring lines A1 and A2 are wiring lines for transmitting the address signal ADD, for example, and of these the signal wiring line A1 is connected to a corresponding bump electrode PLA and the signal wiring line A2 is connected to a corresponding test pad TPA. The signal wiring lines A1 and A2 are short-circuited at a node N5, and are supplied by way of a signal wiring line A3 to the input first-stage circuit 31.

According to said configuration, the timing with which the address signal ADD reaches the input first-stage circuit 31 is substantially the same when the external address signal ADD is supplied from the bump electrode PLA, in other words during normal operation, and when the address signal ADD is supplied from the test pad TPA, in other words during operational testing in the wafer state. The operation of the input first-stage circuit 31 during normal operation can therefore be accurately reproduced during operational tests in the wafer state. In this case, it is more preferable if the parasitic capacitance of the signal wiring line A1 and the parasitic capacitance of the signal wiring line A2 substantially coincide. The time constant of the signal wiring line A1 and the time constant of the signal wiring line A2 are thus made to coincide substantially, and it is therefore possible to make the operating conditions during normal operation and during test operation coincide more accurately.

As described hereinabove, according to this mode of embodiment, the operating conditions during normal operation and during test operation substantially coincide, thereby eliminating situations in which products are mistakenly determined to be non-defective, or are conversely mistakenly determined to be defective. The product yield can thus be improved and the manufacturing cost can be reduced.

In the abovementioned exemplary embodiments, only the configuration in the region D in FIG. 6, in other words at the periphery of the channel A, is described in detail, but other regions in the semiconductor chip in FIG. 6, specifically at the periphery of the channels B, C and D, can also have substantially the same configuration as the periphery of the channel A. For example, the structure of the channel D may have the configuration of the periphery of the channel A illustrated in FIG. 8, reflected about the row of test pads TP. Further, the channels B and C may have a configuration in which the structure of the channels A and D is folded about the center of the chip in the X-direction.

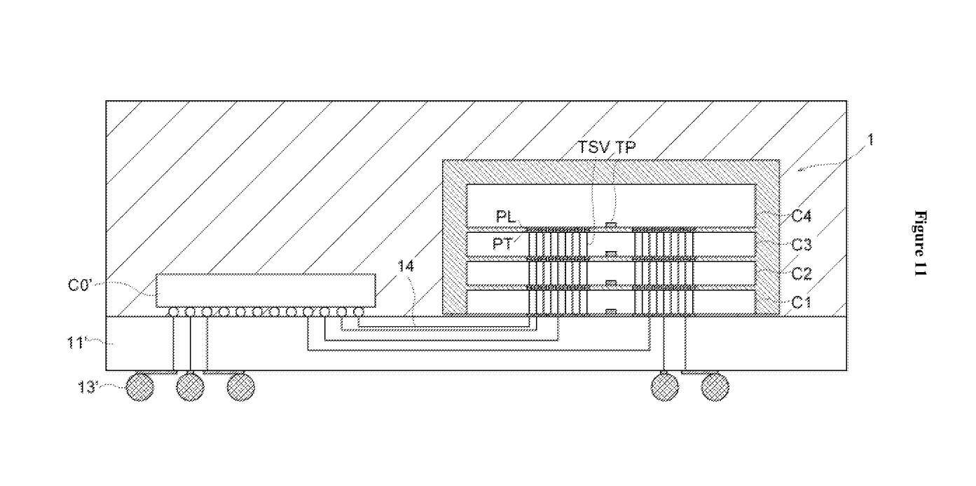

Another mounting example of the semiconductor device illustrated in FIG. 1 will next be described with reference to FIG. 11. In this mounting example, the semiconductor device 1 and a controller chip C0′ are mounted in a planar fashion on an interposer substrate 11′. A plurality of wiring lines 14 are formed on the obverse surface of the interposer substrate 11′ and/or in the interior thereof. Transmission of signals between the controller chip C0′ and the semiconductor device 1 is implemented by way of the wiring lines 14 in the interposer substrate 11′. The interposer substrate 11′ is preferably a silicon interposer or a glass interposer. Further, the interposer substrate 11′ is provided with through-electrodes TSV penetrating vertically through the substrate, and solder bumps 13′ formed on the lower surface of the substrate. The controller chip C0′ and/or the semiconductor device 1 mounted on the upper surface of the interposer substrate 11′ are electrically connected to external printed circuit boards or the like by way of the through-electrodes TSV and the solder bumps 13′ on the interposer substrate 11′. In this mounting example, the controller chip C0′ should be flip-chip mounted on the interposer substrate 11′, and it is therefore not necessary to create through-electrodes TSV in the controller chip C0′.

Preferred modes of embodiment of the present invention have been described hereinabove, but various modifications to the present invention may be made without deviating from the gist of the present invention, without limitation to the abovementioned modes of embodiment, and it goes without saying that these are also included within the scope of the present invention.

For example, in the abovementioned modes of embodiment, examples are described in which the present invention is applied to a wide I/O-type DRAM, but it goes without saying that the present invention is not limited to this application. The present invention may therefore also be applied to memory devices other than DRAMs, and the present invention may also be applied to semiconductor devices other than memory devices, for example logic-type semiconductor devices. For example, the present invention may also be applied to a stacked-type memory having a structure in which a plurality of semiconductor chips, each of which operates as an independent memory, are stacked on one another, and the interface portion of only one of the plurality of memory chips is used to operate also the remainder of the plurality of semiconductor chip memories. Further, the present invention may for example also be applied to a stacked-type memory in which memory chips, from which the interface section between the controller chip and the memory has been removed, and an interface chip on which only an interface section has been formed, are stacked on one another.

### EXPLANATION OF THE REFERENCE NUMBERS

1 Semiconductor device
2, 3 Internal circuit
10 Composite semiconductor device
11, 11′ Package substrate
12 Bump electrode
13, 13′ Solder bump
14 Wiring line
20 Semiconductor substrate
21 Interlayer insulating film
22 Insulating ring
31 Input first-stage circuit
32 Control circuit
33 Data input and output circuit
34 Internal power-supply generating circuit
A1 to A3 Signal wiring line
B Bump region
BL Bit line
C0 Controller chip
C1 to C4 Semiconductor chip
C1a Main surface of semiconductor chip
Ch_a to Ch_d Channel
D, E Region
GM, LM Mesh-like wiring line
MC Memory cell
N1 to N5 Node
PA Peripheral circuit region
PL, PLA, PLS, PLV, PT Bump electrode
S1 to S5, V1 to V5 Power-supply wiring line
TP, TPA, TPS, TPV Test pad
TSV Through-electrode
WL Word line
WTP Leader wiring line
XDEC Row decoder
YDEC Column decoder

1. A semiconductor device comprising:
a bump electrode;
a test pad;
an internal circuit;
a first wiring line portion connecting the bump electrode to a wiring line node;
a second wiring line portion connecting the test pad to the wiring line node; and
a third wiring line portion connecting the wiring line node to the internal circuit;
wherein the resistance values of the first wiring line portion and the second wiring line portion are substantially equal to one another.

2. The semiconductor device of claim 1, wherein the first to third wiring line portions are power-supply wiring lines which supply an external power-supply potential to the internal circuit.

3. The semiconductor device of claim 2, wherein the internal circuit includes an internal power-supply generating circuit which generates an internal power-supply potential on the basis of the external power-supply potential.

4. The semiconductor device of claim 2, wherein at least a portion of the first wiring line portion is constructed in the shape of a mesh.

5. The semiconductor device of claim 1, wherein the first to third wiring line portions are signal wiring lines which supply signals to the internal circuit.

6. The semiconductor device of claim 5, wherein the resistance values of the first wiring line portion and the second wiring line portion are substantially equal to one another.

7. The semiconductor device of claim 1, comprising a through-electrode which is provided in a position overlapping the bump electrode as seen in a plan view, and which penetrates through the semiconductor substrate.

8. A semiconductor device comprising:
a plurality of semiconductor chips which are stacked on one another, wherein each of the plurality of semiconductor chips comprises:
a bump electrode;
a test pad;
an internal circuit;
a first wiring line portion connecting the bump electrode to a wiring line node;
a second wiring line portion connecting the test pad to the wiring line node; and
a third wiring line portion connecting the wiring line node to the internal circuit, wherein
at least one of the plurality of semiconductor chips is provided with a through-electrode provided penetrating through said semiconductor chip,
the internal circuits contained in each of the plurality of semiconductor chips are commonly connected by way of the bump electrodes and the through-electrodes, and
the resistance values of the first wiring line portion and the second wiring line portion contained in each of the plurality of semiconductor chips are substantially equal to one another.

9. The semiconductor device of claim 8, wherein the bump electrode and the through-electrode are disposed in positions that overlap one another as viewed in the stacking direction.

10. The semiconductor device of claim 8, wherein each of the plurality of semiconductor chips is a memory chip having a memory cell array.

11. The semiconductor device of claim 10, comprising a control chip which controls the plurality of memory chips, and the plurality of memory chips and the control chip are stacked on one another.
